(19) United States
(12) Patent Application Publication
(10) Pub. No.: US 2025/0357366 A1
(43) Pub. Date: Nov. 20, 2025

(54) CHIP PACKAGE STRUCTURE WITH ADHESIVE WALL STRUCTURE AND METHOD FOR FORMING THE SAME

(71) Applicant: Taiwan Semiconductor Manufacturing Company, Ltd., Hsinchu (TW)

(72) Inventors: Hung-Yu CHEN, Hsinchu City (TW); Pu WANG, Hsinchu City (TW); Li-Hui CHENG, New Taipei City (TW)

(21) Appl. No.: 18/668,809

(22) Filed: May 20, 2024

(51) Int. Cl. H01L 23/00; H01L 21/56; H01L 23/367; H01L 23/498; H01L 25/16

(52) U.S. Cl. CPC H01L 23/562; H01L 21/56; H01L 23/3672; H01L 23/3675; H01L 23/49822; H01L 23/49838; H01L 24/16; H01L 24/32; H01L 24/73; H01L 25/16; H01L 2224/16225; H01L 2224/32225; H01L 2224/73204; H01L 2924/1436

(57) ABSTRACT

A method for forming a chip package structure is provided. The method includes disposing a chip structure over a substrate. The method includes forming an adhesive wall structure over the substrate and surrounding the chip structure. The adhesive wall structure has a convex curved sidewall facing away from the chip structure. The method includes forming an adhesive layer over the substrate. The adhesive layer surrounds the adhesive wall structure, and a first Young's modulus of the adhesive layer is different from a second Young's modulus of the adhesive wall structure. The method includes disposing a heat-spreading lid over the adhesive layer to cover the adhesive wall structure and the chip structure. The heat-spreading lid is bonded to the adhesive layer and the adhesive wall structure.

### BACKGROUND

Semiconductor devices are used in a variety of electronic applications, such as personal computers, cell phones, digital cameras, and other electronic equipment. Semiconductor devices are typically fabricated by sequentially depositing insulating layers or dielectric layers, conductive layers, and semiconductor layers over a semiconductor substrate, and patterning the various material layers using photolithography processes and etching processes to form circuit components and elements thereon.

Many integrated circuits (IC) are typically manufactured on a semiconductor wafer. Technological advances in IC materials and design have produced generations of ICs. Each generation has smaller and more complex circuits than the previous generation. The dies of the wafer may be processed and packaged at the wafer level, and various technologies have been developed for wafer level packaging. Since the chip package structure may need to include multiple chips with multiple functions, it is a challenge to form a reliable chip package structure with multiple chips.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1E are cross-sectional views of various stages of a process for forming a chip package structure, in accordance with some embodiments.

FIG. 1B-1 is a top view of the chip package structure of FIG. 1B, in accordance with some embodiments.

FIG. 1C-1 is a top view of the chip package structure of FIG. 1C, in accordance with some embodiments.

FIG. 1D-1 is a bottom perspective view of a heat-spreading lid of the chip package structure of FIG. 1D, in accordance with some embodiments.

FIG. 1E-1 is a top view of the chip package structure of FIG. 1E, in accordance with some embodiments.

FIG. 1E-2 is a cross-sectional view illustrating the chip package structure along a sectional line II-II′ in FIG. 1E-1, in accordance with some embodiments.

FIG. 1E-3 is a cross-sectional view illustrating the chip package structure along a sectional line III-III′ in FIG. 1E-1, in accordance with some embodiments.

FIG. 2 is a cross-sectional view of a chip package structure, in accordance with some embodiments.

FIG. 3 is a cross-sectional view of a chip package structure, in accordance with some embodiments.

FIG. 4A is a cross-sectional view of a chip package structure, in accordance with some embodiments.

FIG. 4B is a top view of the chip package structure of FIG. 4A, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

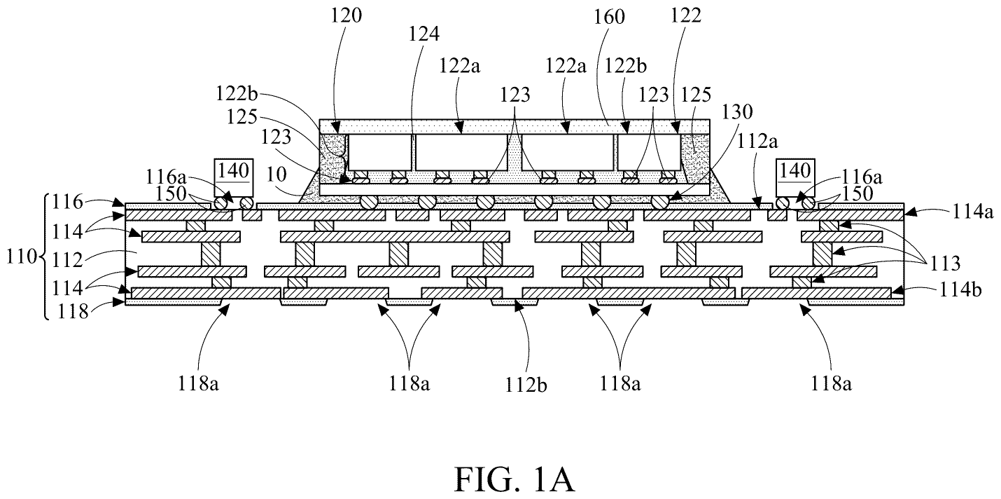

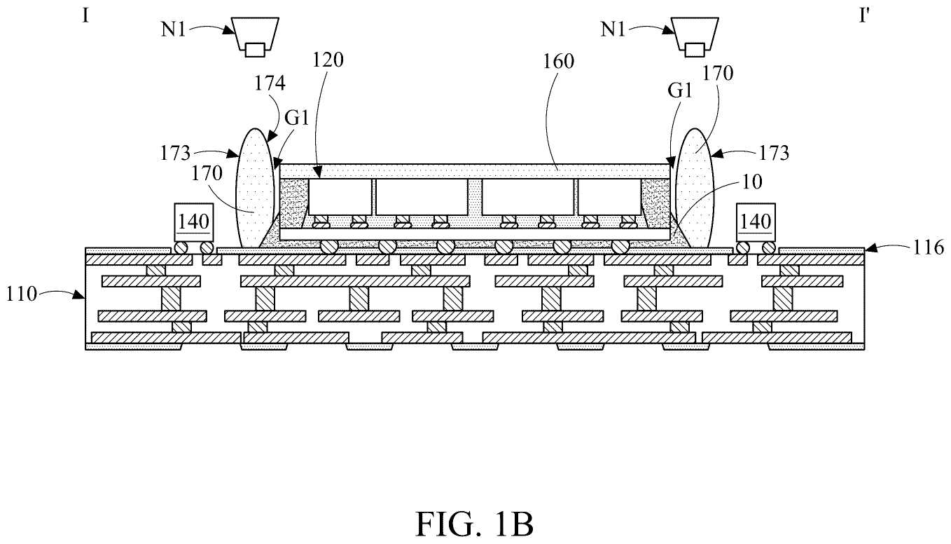

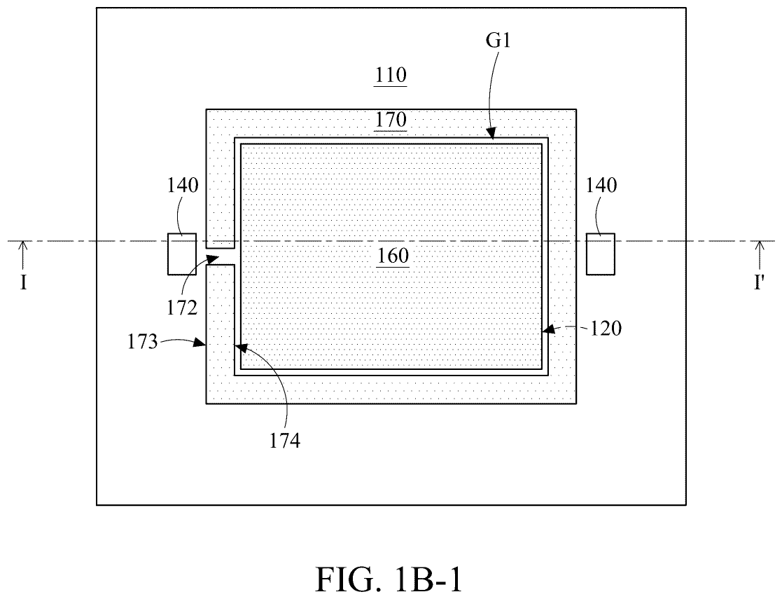

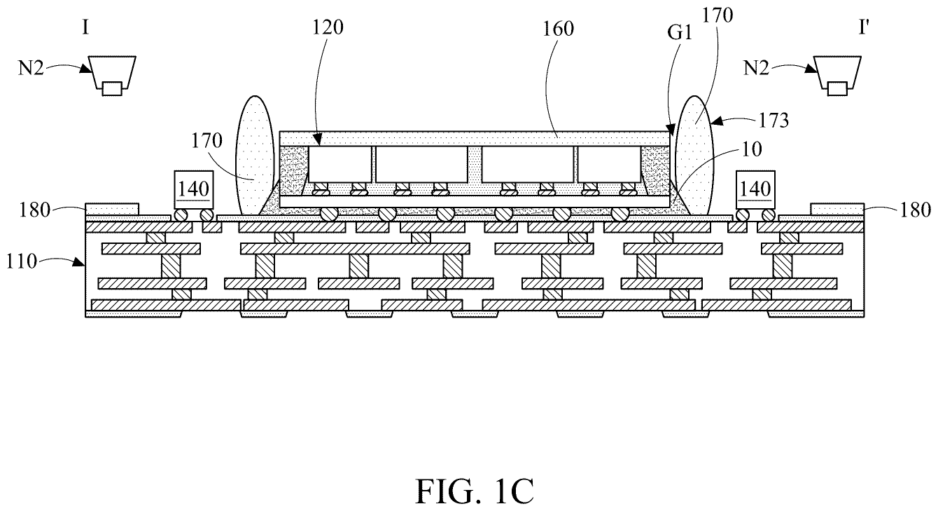

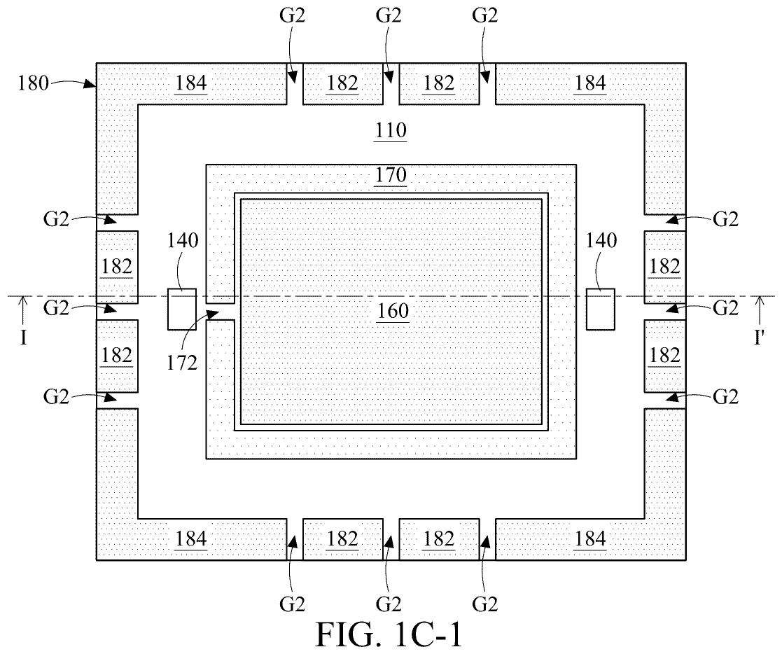

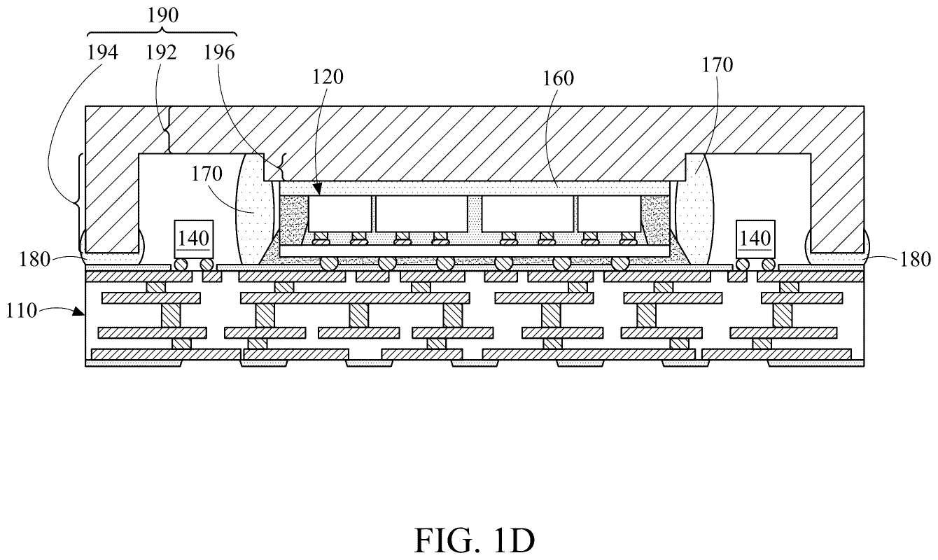

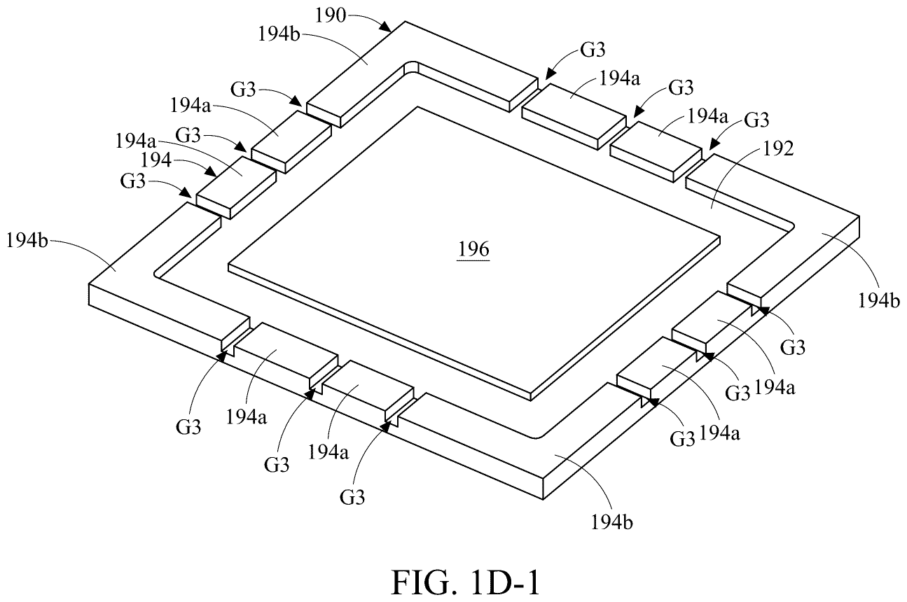

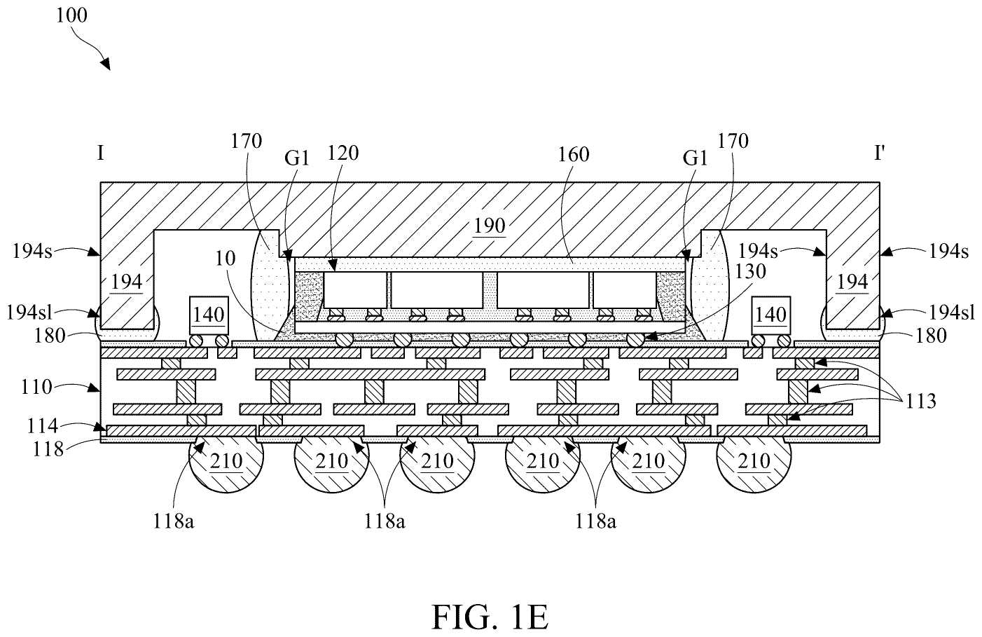

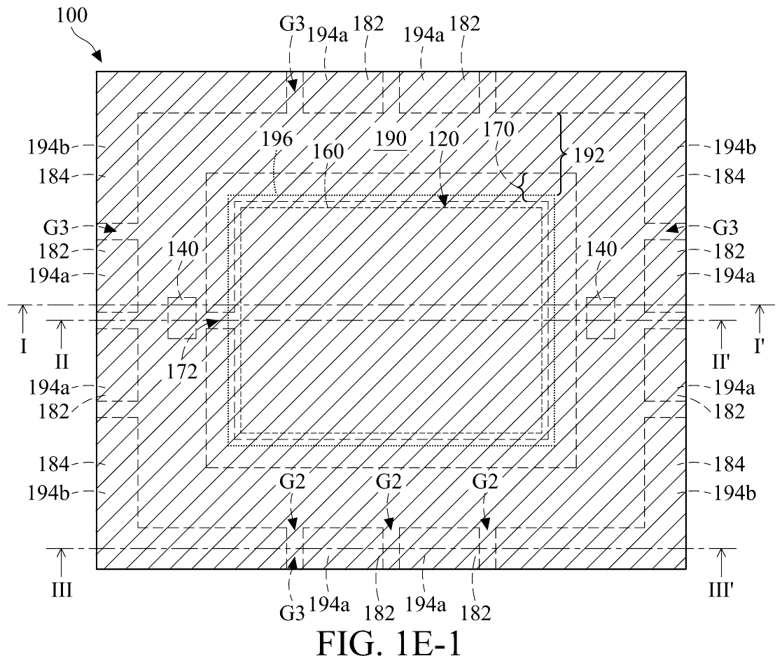

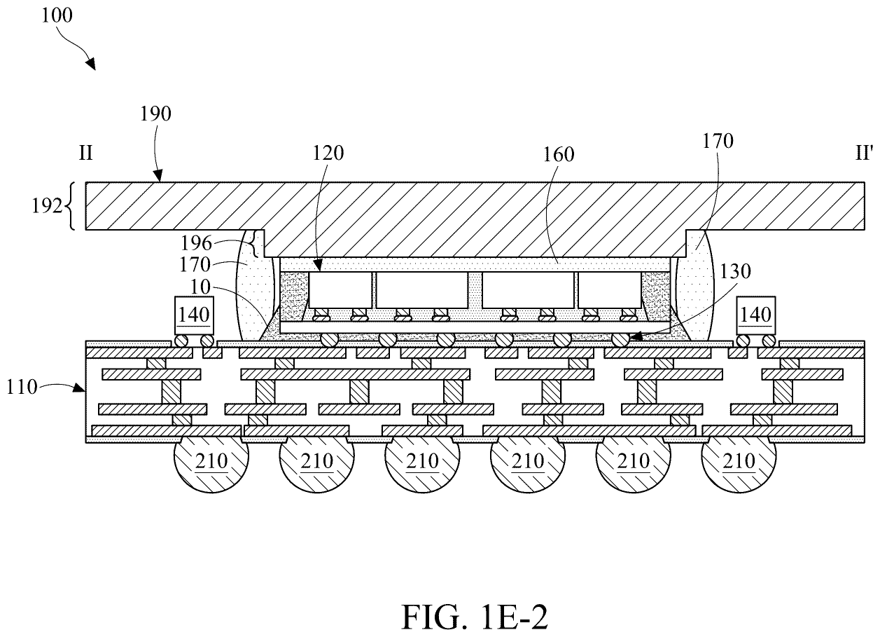

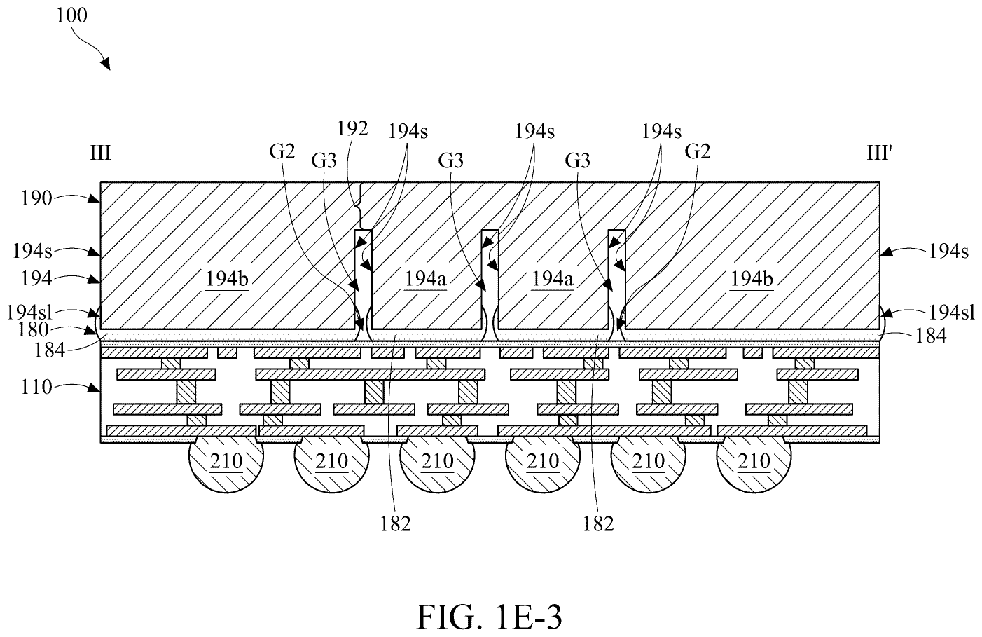

FIGS. 1A-1E are cross-sectional views of various stages of a process for forming a chip package structure, in accordance with some embodiments. As shown in FIG. 1A, a substrate 110 is provided, in accordance with some embodiments. The substrate 110 includes a printed circuit board (PCB), a chip, or another suitable structure with wiring layers and pads.

The substrate 110 includes a dielectric structure 112, conductive vias 113, wiring layers 114, and solder resist layers 116 and 118, in accordance with some embodiments. The wiring layers 114 and the conductive vias 113 are formed in the dielectric structure 112, in accordance with some embodiments. The conductive vias 113 are electrically connected between the wiring layers 114, in accordance with some embodiments.

The solder resist layer 116 is formed over a top surface 112a of the dielectric structure 112, in accordance with some embodiments. The solder resist layer 116 has openings 116a, in accordance with some embodiments. The openings 116a expose portions of the topmost wiring layer 114a (of the wiring layers 114), in accordance with some embodiments.

The solder resist layer 118 is formed over a bottom surface 112b of the dielectric structure 112, in accordance with some embodiments. The solder resist layer 118 has openings 118a, in accordance with some embodiments. The openings 118a expose portions of the bottommost wiring layer 114b (of the wiring layers 114), in accordance with some embodiments.

The dielectric structure 112 is made of an insulating material, such as an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments. Alternatively, the insulating material includes a low-k material or a porous dielectric material having a k-value which is lower than that of silicon oxide, or lower than about 3.0 or about 2.5, in accordance with some embodiments.

The dielectric structure 112 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

The conductive vias 113 and the wiring layers 114 are made of metal (e.g., copper, aluminum, gold, silver, or tungsten) or alloy thereof, in accordance with some embodiments. The solder resist layers 116 and 118 are made of an insulating material, such as a polymer material, in accordance with some embodiments.

As shown in FIG. 1A, a chip package 120 is bonded to the substrate 110 through conductive bumps 130, in accordance with some embodiments. The chip package 120 includes a wiring substrate 121, chip structures 122, solder bumps 123, an underfill layer 124, and a molding layer 125, in accordance with some embodiments.

The wiring substrate 121 includes a dielectric structure, conductive pads, wiring layers, and conductive vias (not shown), in accordance with some embodiments. The conductive pads are embedded in the dielectric structure, in accordance with some embodiments.

The wiring layers and the conductive vias of the wiring substrate 121 are formed in the dielectric structure of the wiring substrate 121, in accordance with some embodiments. The conductive vias are electrically connected between different wiring layers and between the wiring layer and the conductive pads, in accordance with some embodiments.

The dielectric structure is made of an insulating material such as a polymer material (e.g., polybenzoxazole or polyimide), nitride (e.g., silicon nitride), oxide (e.g., silicon oxide), silicon oxynitride, or the like, in accordance with some embodiments. The dielectric structure is formed using lamination process (or deposition processes), photolithography processes, and etching processes, in accordance with some embodiments.

The conductive pads are made of a conductive material, such as metal (e.g. copper, aluminum, or tungsten) or alloys thereof, in accordance with some embodiments. The wiring layers are made of a conductive material, such as metal (e.g. copper, aluminum, or tungsten) or alloys thereof, in accordance with some embodiments. The conductive vias are made of a conductive material, such as metal (e.g. copper, aluminum, or tungsten) or alloys thereof, in accordance with some embodiments.

In some embodiments, the conductive pads, the wiring layers, and the conductive vias are made of the same material. In some other embodiments, the conductive pads, the wiring layers, and the conductive vias are made of different materials.

As shown in FIG. 1A, chip structures 122 are bonded to the wiring substrate 121 through the solder bumps 123, in accordance with some embodiments. In some embodiments, the chip structure 122 includes a chip. The chip includes a substrate, in accordance with some embodiments. In some embodiments, the substrate is made of an elementary semiconductor material including silicon or germanium in a single crystal structure, a polycrystal structure, or an amorphous structure.

In some other embodiments, the substrate is made of a compound semiconductor, such as silicon carbide, gallium arsenide, gallium phosphide, indium phosphide, indium arsenide, an alloy semiconductor, such as SiGe, or GaAsP, or a combination thereof. The substrate may also include multi-layer semiconductors, semiconductor on insulator (SOI) (such as silicon on insulator or germanium on insulator), or a combination thereof.

In some embodiments, the substrate includes various device elements. In some embodiments, the various device elements are formed in and/or over the substrate. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to define active regions and electrically isolate various device elements formed in and/or over the substrate in the active regions. In some embodiments, the isolation features include shallow trench isolation (STI) features, local oxidation of silicon (LOCOS) features, other suitable isolation features, or a combination thereof.

In some other embodiments, the chip structure 122 includes a chip package, such as a dynamic random access memory (DRAM) package or a high bandwidth memory (HBM) package. The chip package includes a chip scale package, such as a wafer level chip scale package. In some embodiments, the chip package includes one chip. In some other embodiments, the chip package includes multiple chips, which are arranged side by side or stacked with each other (e.g., a 3D packaging or a 3DIC device).

In some embodiments, the chip structures 122 include chip structures 122a and 122b. The chip structures 122a include chips such as graphic processing unit (GPU) chips, and the chip structures 122b include chip packages such as high bandwidth memory (HBM) packages, in accordance with some embodiments. The solder bumps 123 are made of tin (Sn) or another suitable conductive material, in accordance with some embodiments.

The underfill layer 124 is formed between the chip structures 122 and the wiring substrate 121, in accordance with some embodiments. The underfill layer 124 surrounds the solder bumps 123 and the chip structures 122, in accordance with some embodiments. The underfill layer 124 is made of an insulating material, such as a polymer material, in accordance with some embodiments. The underfill layer 124 is formed using a filling process and a curing process, in accordance with some embodiments.

As shown in FIG. 1A, the molding layer 125 is formed over the wiring substrate 121, in accordance with some embodiments. The molding layer 125 surrounds the chip structures 122 and the underfill layer 124, in accordance with some embodiments. The molding layer 125 is made of an insulating material, such as a polymer material, in accordance with some embodiments. The conductive bumps 130 are made of tin (Sn) or another suitable conductive material, in accordance with some embodiments.

As shown in FIG. 1A, an underfill layer 10 is formed between the chip package 120 and the substrate 110, in accordance with some embodiments. The underfill layer 10 surrounds the conductive bumps 130 and the chip package 120, in accordance with some embodiments. The underfill layer 10 is made of an insulating material, such as a polymer material, in accordance with some embodiments. The underfill layer 10 is formed using a filling process and a curing process, in accordance with some embodiments.

As shown in FIG. 1A, devices 140 are bonded to the substrate 110 through conductive bumps 150, in accordance with some embodiments. The devices 140 include passive devices, other suitable devices, or combinations thereof. The passive devices include resistors, capacitors, inductors, or other suitable passive devices. The conductive bumps 150 are made of tin (Sn) or another suitable conductive material, in accordance with some embodiments.

As shown in FIG. 1A, a heat conductive layer 160 is formed over the chip package 120, in accordance with some embodiments. The heat conductive layer 160 is a film structure, in accordance with some embodiments. Therefore, the heat conductive layer 160 is also referred to as a heat conductive film, in accordance with some embodiments. In some embodiments, the thermal conductivity of the heat conductive layer 160 is greater than the thermal conductivity of the chip package 120.

The heat conductive layer 160 is made of a metal material (e.g., Sn, Ag, Au, or In), an alloy material thereof, or a polymer material doped with a high thermal conductivity material (e.g., graphite, carbon, graphene, or metal), in accordance with some embodiments.

The polymer material includes epoxy, in accordance with some embodiments. The heat conductive layer 160 is formed using a lamination process, in accordance with some embodiments. In some other embodiments, the heat conductive layer 160 is formed using a dispensing process.

FIG. 1B-1 is a top view of the chip package structure of FIG. 1B, in accordance with some embodiments. FIG. 1B is a cross-sectional view illustrating the chip package structure along a sectional line I-I′ in FIG. 1B-1, in accordance with some embodiments.

As shown in FIGS. 1B and 1B-1, an adhesive wall structure 170 is formed over the substrate 110, in accordance with some embodiments. The adhesive wall structure 170 is in direct contact with the substrate 110, in accordance with some embodiments. The adhesive wall structure 170 surrounds the chip package 120 and the heat conductive layer 160, in accordance with some embodiments.

The adhesive wall structure 170 has a convex curved outer sidewall 173 and a convex curved inner sidewall 174, in accordance with some embodiments. The convex curved outer sidewall 173 faces away from the chip package 120, in accordance with some embodiments. The convex curved inner sidewall 174 faces the chip package 120, in accordance with some embodiments.

The chip package 120 and the adhesive wall structure 170 are spaced apart from each other, in accordance with some embodiments. In some embodiments, there is a gap G1 between the chip package 120 and the adhesive wall structure 170. The gap G1 is also between the heat conductive layer 160 and the adhesive wall structure 170, in accordance with some embodiments. The gap G1 is an air gap, in accordance with some embodiments. The adhesive wall structure 170 is in contact with the underfill layer 10, in accordance with some embodiments. The adhesive wall structure 170 is in contact with the solder resist layer 116, in accordance with some embodiments.

As shown in FIG. 1B-1, the adhesive wall structure 170 has a gap 172, in accordance with some embodiments. The air in the gap G1 can flow out through the gap 172 during the subsequent lid bonding process, in accordance with some embodiments. The adhesive wall structure 170 has a C-like shape, in accordance with some embodiments. The gap 172 is between the heat conductive layer 160 and the device 140, in accordance with some embodiments. In some other embodiments (not shown), the gap 172 is not between the heat conductive layer 160 and the device 140.

The adhesive wall structure 170 is made of a polymer material such as silicone, epoxy, an acrylic material, the like, or another suitable material, in accordance with some embodiments. In some other embodiments, the adhesive wall structure 170 is made of a polymer material doped with a high thermal conductivity material (e.g., graphite, carbon, graphene, or metal). The polymer material includes epoxy, in accordance with some embodiments.

The adhesive wall structure 170 and the heat conductive layer 160 are made of different materials, in accordance with some embodiments. The thermal conductivity of the heat conductive layer 160 is greater than that of the adhesive wall structure 170, in accordance with some embodiments.

The adhesive wall structure 170 has a gel form and is formed using a dispensing process, which uses nozzles N1, in accordance with some embodiments. In some other embodiments, the adhesive wall structure 170 is a film structure and the adhesive wall structure 170 is formed using a lamination process.

FIG. 1C-1 is a top view of the chip package structure of FIG. 1C, in accordance with some embodiments. FIG. 1C is a cross-sectional view illustrating the chip package structure along a sectional line I-I′ in FIG. 1C-1, in accordance with some embodiments. As shown in FIGS. 1C and 1C-1, an adhesive layer 180 is formed over the substrate 110, in accordance with some embodiments. The adhesive layer 180 is in direct contact with the substrate 110, in accordance with some embodiments.

The adhesive layer 180 surrounds the adhesive wall structure 170, in accordance with some embodiments. In some embodiments, a first Young's modulus of the adhesive layer 180 is different from a second Young's modulus of the adhesive wall structure 170. In some embodiments, a first elongation rate of the adhesive layer 180 is different from a second elongation rate of the adhesive wall structure 170.

The adhesive layer 180 has portions 182 and 184, in accordance with some embodiments. The portions 182 and 184 are spaced apart from each other by gaps G2, in accordance with some embodiments. The air surrounded by the adhesive layer 180 can flow out through the gaps G2 during the subsequent lid bonding process, in accordance with some embodiments. The portion 182 has a straight strip shape, in accordance with some embodiments. The portion 184 has an L shape, in accordance with some embodiments. In some embodiments, the gap 172 is aligned with the gap G2. In some other embodiments, the gap 172 is misaligned with the gap G2.

The adhesive layer 180 is made of a polymer material such as silicone, epoxy, an acrylic material, the like, or another suitable material, in accordance with some embodiments. The adhesive layer 180 is formed using a dispensing process, which uses nozzles N2, in accordance with some embodiments.

In some other embodiments, the adhesive layer 180 is a film structure and the adhesive layer 180 is formed using a lamination process. In some optional embodiments, the adhesive layer 180 is formed before the adhesive wall structure 170 is formed.

FIG. 1D-1 is a bottom perspective view of a heat-spreading lid of the chip package structure of FIG. 1D, in accordance with some embodiments. As shown in FIGS. 1D and 1D-1, a heat-spreading lid 190 is bonded to the adhesive layer 180 to cover the adhesive wall structure 170, the heat conductive layer 160, and the chip package 120, in accordance with some embodiments. The heat-spreading lid 190 is directly bonded to the adhesive layer 180, the adhesive wall structure 170, and the heat conductive layer 160, in accordance with some embodiments.

The heat-spreading lid 190 is harder than the substrate 110, in accordance with some embodiments. That is, the hardness of the heat-spreading lid 190 is greater than that of the substrate 110, in accordance with some embodiments. Therefore, the warpage of the substrate 110 is reduced after the heat-spreading lid 190 is bonded to the substrate 110, in accordance with some embodiments. The thermal expansion coefficient of the heat-spreading lid 190 is less than the thermal expansion coefficient of the substrate 110, in accordance with some embodiments.

The heat-spreading lid 190 has a lid portion 192, a foot portion 194, and a protruding portion 196, in accordance with some embodiments. The lid portion 192 is over the foot portion 194 and the protruding portion 196, in accordance with some embodiments.

The foot portion 194 surrounds the protruding portion 196, the chip package 120, and the adhesive wall structure 170, in accordance with some embodiments. The foot portion 194 has portions 194a and 194b, in accordance with some embodiments. The portions 194a and 194b are spaced apart from each other by gaps G3, in accordance with some embodiments.

The gaps G3 can release the stress of the heat-spreading lid 190, in accordance with some embodiments. The air surrounded by the foot portion 194 can flow out through the gaps G3 during the lid bonding process, in accordance with some embodiments. The portion 194a has a straight strip shape, in accordance with some embodiments. The portion 194b has an L shape, in accordance with some embodiments.

The protruding portion 196 is over the heat conductive layer 160, in accordance with some embodiments. The protruding portion 196 is surrounded by the adhesive wall structure 170, in accordance with some embodiments. The protruding portion 196 is in contact with the adhesive wall structure 170, in accordance with some embodiments.

The heat-spreading lid 190 is made of a high thermal conductivity material, such as a metal material (aluminum or copper), an alloy material (e.g., stainless steel), or aluminum-silicon carbide (AlSiC), in accordance with some embodiments.

After the heat-spreading lid 190 is bonded to the adhesive layer 180, a curing process is performed to crosslink the polymer material of the adhesive wall structure 170 and the adhesive layer 180, in accordance with some embodiments. The curing temperature ranges from about 100 degree C. to 200 degree C., in accordance with some embodiments. The adhesive wall structure 170 is harder than the heat conductive layer 160, in accordance with some embodiments. That is, the hardness of the adhesive wall structure 170 is greater than that of the heat conductive layer 160, in accordance with some embodiments.

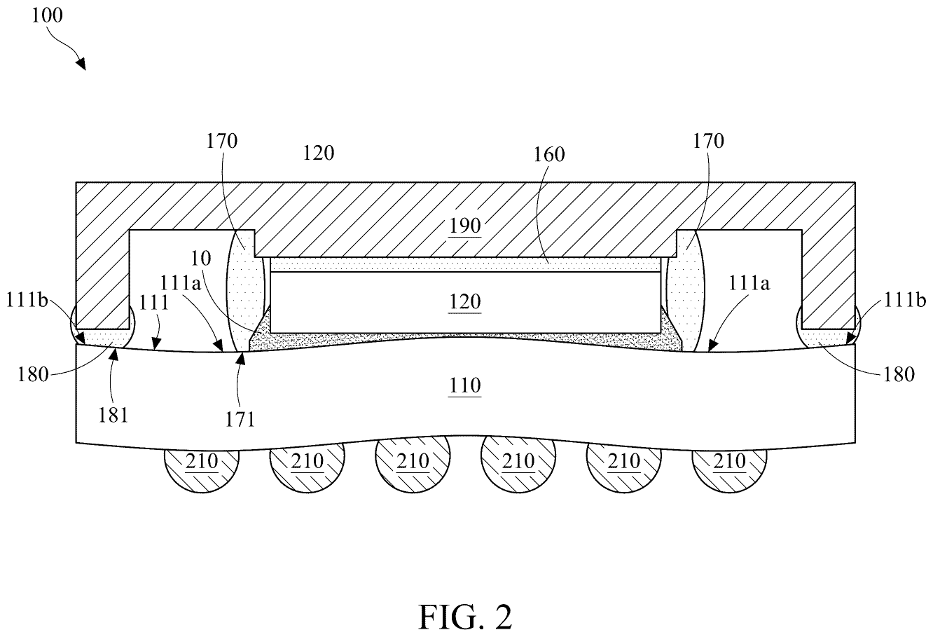

FIG. 1E-1 is a top view of the chip package structure of FIG. 1E, in accordance with some embodiments. FIG. 1E is a cross-sectional view illustrating the chip package structure along a sectional line I-I′ in FIG. 1E-1, in accordance with some embodiments. FIG. 1E-2 is a cross-sectional view illustrating the chip package structure along a sectional line II-II′ in FIG. 1E-1, in accordance with some embodiments.

As shown in FIGS. 1E, 1E-1 and 1E-2, conductive bumps 210 are formed in the openings 118a of the solder resist layer 118, in accordance with some embodiments. In this step, a chip package structure 100 is substantially formed, in accordance with some embodiments.

The conductive bumps 210 are electrically connected to the wiring layers 114, in accordance with some embodiments. The chip package 120 is electrically connected to the conductive bumps 210 through the wiring layers 114 and the conductive vias 113, in accordance with some embodiments. The conductive bumps 210 are made of tin (Sn) or another suitable conductive material, in accordance with some embodiments.

FIG. 1E-3 is a cross-sectional view illustrating the chip package structure along a sectional line III-III′ in FIG. 1E-1, in accordance with some embodiments. As shown in FIGS. 1E and 1E-3, the adhesive layer 180 covers lower portions 194s1 of the sidewalls 194s of the foot portion 194, in accordance with some embodiments. The gaps G3 are over the corresponding gaps G2, in accordance with some embodiments.

Since different portions of the substrate 110 may have different warpage behavior after annealing processes, curing processes, or the like, the first Young's modulus of the adhesive layer 180 and the second Young's modulus of the adhesive wall structure 170 can be designed as required to reduce the warpage of the substrate 110, in accordance with some embodiments.

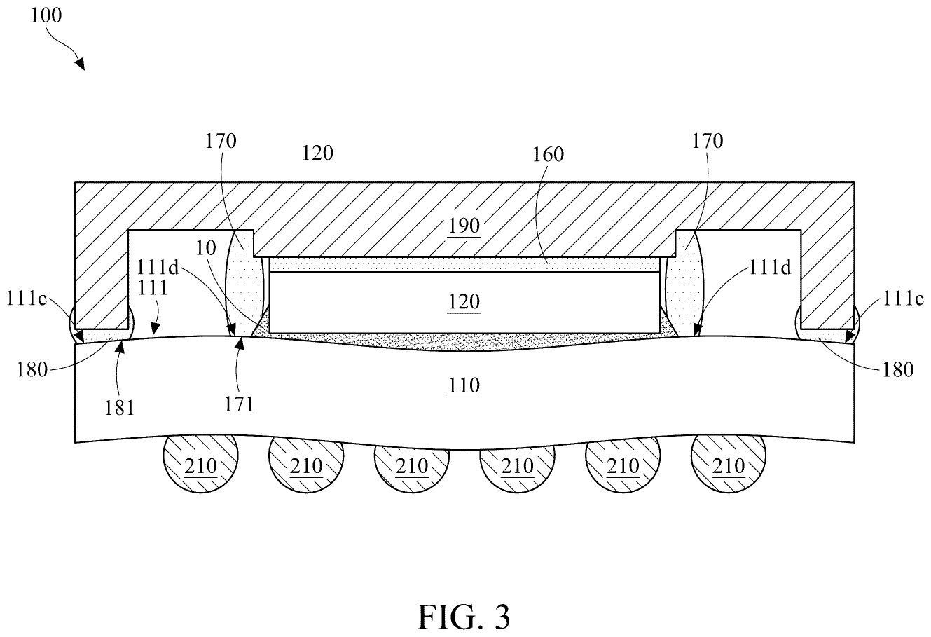

Similarly, the first elongation rate of the adhesive layer 180 and the second elongation rate of the adhesive wall structure 170 can be designed as required, in accordance with some embodiments. The design methods are illustrated in FIGS. 2 and 3, in accordance with some embodiments.

FIG. 2 is a cross-sectional view of the chip package structure 100 after annealing processes, curing processes, or the like, in accordance with some embodiments. For the sake of simplicity, FIG. 2 omits the conductive bumps 130, the devices 140, and the conductive bumps 150, in accordance with some embodiments.

For example, as shown in FIG. 2, the substrate 110 has a top surface 111, in accordance with some embodiments. The top surface 111 has a recess 111a, in accordance with some embodiments. The adhesive wall structure 170 is in the recess 111a, in accordance with some embodiments. In some embodiments, a bottom surface 171 of the adhesive wall structure 170 is lower than a bottom surface 181 of the adhesive layer 180.

The adhesive wall structure 170 may have the second Young's modulus greater than the first Young's modulus of the adhesive layer 180 to increase the gripping force of the adhesive wall structure 170 between the heat-spreading lid 190 and the substrate 110.

Therefore, the adhesive wall structure 170 can apply more lifting stress to the portion of the substrate 110 under the recess 111a to reduce the depth of the recess 111a, which reduces warpage of the substrate 110 and thereby prevents cracks between the heat-spreading lid 190 and the heat conductive layer 160, in accordance with some embodiments. Therefore, the yield of the chip package structure 100 is improved, in accordance with some embodiments.

The first Young's modulus of the adhesive layer 180 ranges from about 8 MPa to 16 MPa, in accordance with some embodiments. The second Young's modulus of the adhesive wall structure 170 ranges from about 70 MPa to 100 MPa, in accordance with some embodiments. The adhesive wall structure 170 is harder than the adhesive layer 180, in accordance with some embodiments.

The top surface 111 has a convex portion 111b, in accordance with some embodiments. The adhesive layer 180 is over the convex portion 111b, in accordance with some embodiments. The first elongation rate of the adhesive layer 180 is greater than the second elongation rate of the adhesive wall structure 170, and the first Young's modulus of the adhesive layer 180 is less than the second Young's modulus of the adhesive wall structure 170.

Therefore, the adhesive layer 180 can serve as a buffer layer between the heat-spreading lid 190 and the substrate 110, which can prevent the portion of the substrate 110 under the convex portion 111b from being affected (or lifted) by the heat-spreading lid 190, in accordance with some embodiments. As a result, the warpage of the substrate 110 is reduced, in accordance with some embodiments.

The first elongation rate of the adhesive layer 180 ranges from about 170% to 210%, in accordance with some embodiments. The second elongation rate of the adhesive wall structure 170 ranges from about 30% to 60%, in accordance with some embodiments. The adhesive layer 180 is softer than the adhesive wall structure 170, in accordance with some embodiments.

FIG. 3 is a cross-sectional view of the chip package structure 100 after annealing processes, curing processes, or the like, in accordance with some embodiments. For the sake of simplicity, FIG. 3 omits the conductive bumps 130, the devices 140, and the conductive bumps 150, in accordance with some embodiments.

For example, as shown in FIG. 3, the substrate 110 has a top surface 111, in accordance with some embodiments. The top surface 111 has a recess portion 111c and a convex portion 111d, in accordance with some embodiments. The adhesive wall structure 170 is over the convex portion 111d, in accordance with some embodiments.

The adhesive layer 180 is over the recess portion 111c, in accordance with some embodiments. The bottom surface 181 of the adhesive layer 180 is lower than the bottom surface 171 of the adhesive wall structure 170, in accordance with some embodiments.

The first Young's modulus of the adhesive layer 180 is greater than the second Young's modulus of the adhesive wall structure 170, which increases the gripping force of the adhesive layer 180 between the heat-spreading lid 190 and the substrate 110. Therefore, the adhesive layer 180 can apply more lifting stress to the portion of the substrate 110 under the recess portion 111c to reduce warpage of the substrate 110, in accordance with some embodiments.

The first Young's modulus of the adhesive layer 180 ranges from about 70 MPa to 100 MPa, in accordance with some embodiments. The second Young's modulus of the adhesive wall structure 170 ranges from about 8 MPa to 16 MPa, in accordance with some embodiments. The adhesive layer 180 is harder than the adhesive wall structure 170, in accordance with some embodiments.

The second elongation rate of the adhesive wall structure 170 is greater than the first elongation rate of the adhesive layer 180, and the second Young's modulus of the adhesive wall structure 170 is less than the first Young's modulus of the adhesive layer 180, in accordance with some embodiments.

Therefore, the adhesive wall structure 170 can serve as a buffer layer between the heat-spreading lid 190 and the substrate 110, which can prevent the portion of the substrate 110 under the convex portion 111d from being affected (or lifted) by the heat-spreading lid 190, in accordance with some embodiments.

As a result, the warpage of the substrate 110 is reduced, which prevents cracks between the heat-spreading lid 190 and the heat conductive layer 160, in accordance with some embodiments. Therefore, the yield of the chip package structure 100 is improved, in accordance with some embodiments.

The first elongation rate of the adhesive layer 180 ranges from about 30% to 60%, in accordance with some embodiments. The second elongation rate of the adhesive wall structure 170 ranges from about 170% to 210%, in accordance with some embodiments. The adhesive wall structure 170 is softer than the adhesive layer 180, in accordance with some embodiments.

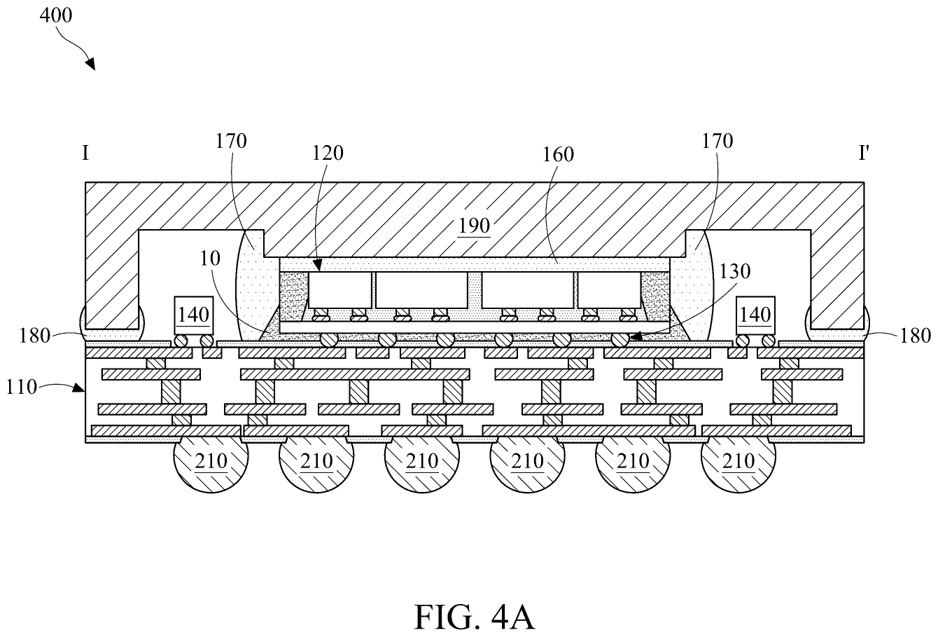

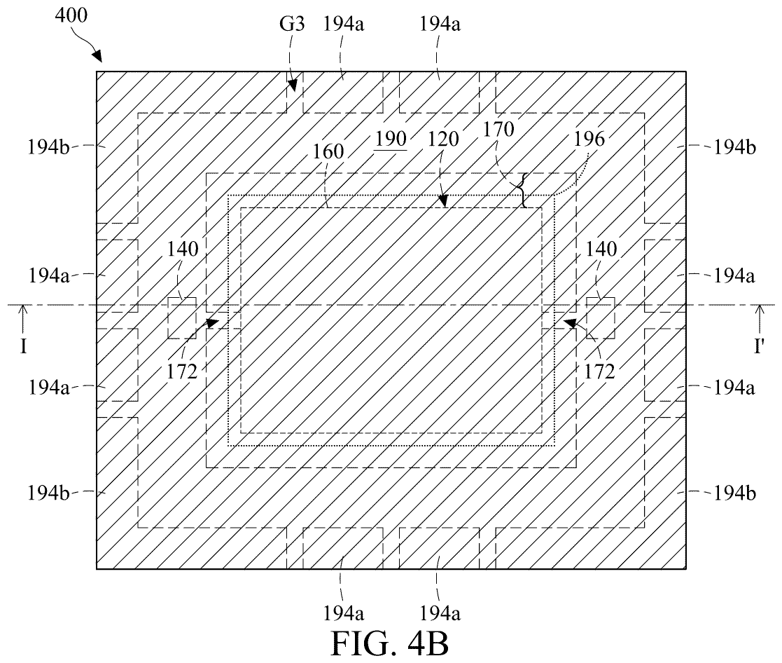

FIG. 4A is a cross-sectional view of a chip package structure 400, in accordance with some embodiments. FIG. 4B is a top view of the chip package structure 400 of FIG. 4A, in accordance with some embodiments. FIG. 4A is a cross-sectional view illustrating the chip package structure 400 along a sectional line I-I′ in FIG. 4B, in accordance with some embodiments.

As shown in FIGS. 4A and 4B, the chip package structure 400 is similar to the chip package structure 100 of FIG. 1E, except that there is no gap between the adhesive wall structure 170 and the chip package 120 of the chip package structure 400, and the adhesive wall structure 170 has gaps 172, in accordance with some embodiments.

That is, the adhesive wall structure 170 is in direct contact with the chip package 120, in accordance with some embodiments. The adhesive wall structure 170 is in direct contact with the heat conductive layer 160, in accordance with some embodiments.

The adhesion force of the adhesive wall structure 170 to the chip package 120 is greater than the adhesion force of the heat conductive layer 160 to the chip package 120, in accordance with some embodiments.

Processes and materials for forming the chip package structure 400 may be similar to, or the same as, those for forming the chip package structure 100 described above.

Elements designated by the same or similar reference numbers as those in FIGS. 1A to 4B have the same or similar structures and the materials. Therefore, the detailed descriptions thereof will not be repeated herein.

In accordance with some embodiments, chip package structures and methods for forming the same are provided. The methods (for forming the chip package structures) form an adhesive wall structure and an adhesive layer connected between a substrate and a heat-spreading lid, and the adhesive wall structure is between the chip structure and the adhesive layer. A first Young's modulus of the adhesive layer is different from a second Young's modulus of the adhesive wall structure. The first Young's modulus of the adhesive layer and the second Young's modulus of the adhesive wall structure can be designed as required to reduce the warpage of the substrate. Therefore, the yield of the chip package structure is improved.

In accordance with some embodiments, a method for forming a chip package structure is provided. The method includes disposing a chip structure over a substrate. The method includes forming an adhesive wall structure over the substrate and surrounding the chip structure. The adhesive wall structure has a convex curved sidewall facing away from the chip structure. The method includes forming an adhesive layer over the substrate. The adhesive layer surrounds the adhesive wall structure, and a first Young's modulus of the adhesive layer is different from a second Young's modulus of the adhesive wall structure. The method includes disposing a heat-spreading lid over the adhesive layer to cover the adhesive wall structure and the chip structure. The heat-spreading lid is bonded to the adhesive layer and the adhesive wall structure.

In accordance with some embodiments, a method for forming a chip package structure is provided. The method includes disposing a chip structure over a substrate. The method includes forming an adhesive wall structure over the substrate and surrounding the chip structure. The adhesive wall structure has a convex curved sidewall facing the chip structure. The method includes forming an adhesive layer over the substrate. The adhesive layer surrounds the adhesive wall structure, and a first elongation rate of the adhesive layer is different from a second elongation rate of the adhesive wall structure. The method includes disposing a heat-spreading lid over the adhesive layer to cover the adhesive wall structure and the chip structure. The adhesive layer and the adhesive wall structure are in direct contact with the substrate and the heat-spreading lid.

In accordance with some embodiments, a chip package structure is provided. The chip package structure includes a substrate. The chip package structure includes a chip structure over the substrate. The chip package structure includes an adhesive wall structure over the substrate and surrounding the chip structure. The adhesive wall structure has a convex curved sidewall facing away from the chip structure. The chip package structure includes an adhesive layer over the substrate and surrounding the adhesive wall structure. A first Young's modulus of the adhesive layer is different from a second Young's modulus of the adhesive wall structure. The chip package structure includes a heat-spreading lid over the adhesive layer, the adhesive wall structure, and the chip structure. The heat-spreading lid is bonded to the adhesive layer and the adhesive wall structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a chip package structure, comprising:
disposing a chip structure over a substrate;
forming an adhesive wall structure over the substrate and surrounding the chip structure, wherein the adhesive wall structure has a convex curved sidewall facing away from the chip structure;
forming an adhesive layer over the substrate, wherein the adhesive layer surrounds the adhesive wall structure, and a first Young's modulus of the adhesive layer is different from a second Young's modulus of the adhesive wall structure; and
disposing a heat-spreading lid over the adhesive layer to cover the adhesive wall structure and the chip structure, wherein the heat-spreading lid is bonded to the adhesive layer and the adhesive wall structure.

2. The method for forming the chip package structure as claimed in claim 1, wherein the second Young's modulus of the adhesive wall structure is greater than the first Young's modulus of the adhesive layer.

3. The method for forming the chip package structure as claimed in claim 2, wherein a first bottom surface of the adhesive wall structure is lower than a second bottom surface of the adhesive layer.

4. The method for forming the chip package structure as claimed in claim 3, wherein the substrate has a top surface having a recess, and the adhesive wall structure is in the recess.

5. The method for forming the chip package structure as claimed in claim 1, wherein the first Young's modulus of the adhesive layer is greater than the second Young's modulus of the adhesive wall structure.

6. The method for forming the chip package structure as claimed in claim 5, wherein a first bottom surface of the adhesive layer is lower than a second bottom surface of the adhesive wall structure.

7. The method for forming the chip package structure as claimed in claim 6, wherein the substrate has a top surface having a recess portion, and the adhesive layer is over the recess portion.

8. The method for forming the chip package structure as claimed in claim 1, wherein there is a gap between the chip structure and the adhesive wall structure.

9. The method for forming the chip package structure as claimed in claim 8, wherein the gap is an air gap.

10. The method for forming the chip package structure as claimed in claim 1, further comprising:
forming a heat conductive layer over the chip structure, wherein the adhesive wall structure further surrounds the heat conductive layer.

11. A method for forming a chip package structure, comprising:
disposing a chip structure over a substrate;
forming an adhesive wall structure over the substrate and surrounding the chip structure, wherein the adhesive wall structure has a convex curved sidewall facing the chip structure;
forming an adhesive layer over the substrate, wherein the adhesive layer surrounds the adhesive wall structure, and a first elongation rate of the adhesive layer is different from a second elongation rate of the adhesive wall structure; and
disposing a heat-spreading lid over the adhesive layer to cover the adhesive wall structure and the chip structure, wherein the adhesive layer and the adhesive wall structure are in contact with the substrate and the heat-spreading lid.

12. The method for forming the chip package structure as claimed in claim 11, wherein the first elongation rate of the adhesive layer is greater than the second elongation rate of the adhesive wall structure, and a first Young's modulus of the adhesive layer is less than a second Young's modulus of the adhesive wall structure.

13. The method for forming the chip package structure as claimed in claim 12, wherein the substrate has a top surface having a recess, and the recess is under the adhesive wall structure.

14. The method for forming the chip package structure as claimed in claim 11, wherein the first elongation rate of the adhesive layer is less than the second elongation rate of the adhesive wall structure, and a first Young's modulus of the adhesive layer is greater than a second Young's modulus of the adhesive wall structure.

15. The method for forming the chip package structure as claimed in claim 14, wherein the substrate has a top surface having a convex portion, and the adhesive wall structure is over the convex portion.

16. A chip package structure, comprising:
a substrate;
a chip structure over the substrate;
an adhesive wall structure over the substrate and surrounding the chip structure, wherein the adhesive wall structure has a convex curved sidewall facing away from the chip structure;
an adhesive layer over the substrate and surrounding the adhesive wall structure, wherein a first Young's modulus of the adhesive layer is different from a second Young's modulus of the adhesive wall structure; and
a heat-spreading lid over the adhesive layer, the adhesive wall structure, and the chip structure, wherein the heat-spreading lid is bonded to the adhesive layer and the adhesive wall structure.

17. The chip package structure as claimed in claim 16, wherein the first Young's modulus of the adhesive layer is less than the second Young's modulus of the adhesive wall structure.

18. The chip package structure as claimed in claim 17, wherein a first elongation rate of the adhesive layer is greater than a second elongation rate of the adhesive wall structure.

19. The chip package structure as claimed in claim 16, wherein the first Young's modulus of the adhesive layer is greater than the second Young's modulus of the adhesive wall structure.

20. The chip package structure as claimed in claim 19, wherein a first elongation rate of the adhesive layer is less than a second elongation rate of the adhesive wall structure.
